(19) United States
(12) Patent Application Publication
(10) Pub. No.: US 2021/0109449 A1
(43) Pub. Date: Apr. 15, 2021

(54) HARDMASK COMPOSITION, HARDMASK LAYER AND METHOD OF FORMING PATTERNS

(71) Applicant: SAMSUNG SDI CO., LTD., Yongin-si (KR)

(72) Inventors: Seunghyun KIM, Suwon-si (KR); Hyeonil JUNG, Suwon-si (KR); Sangmi KIM, Suwon-si (KR); Young Keun KIM, Suwon-si (KR); Sangchol PARK, Suwon-si (KR)

(21) Appl. No.: 17/064,115

(22) Filed: Oct. 6, 2020

(30) Foreign Application Priority Data
Oct. 14, 2019 (KR) 10-2019-0127125

(51) Int. Cl. G03F 7/11; G03F 7/09; G03F 7/20; G03F 7/004; G03F 7/16

(52) U.S. Cl. CPC G03F 7/11; G03F 7/094; G03F 7/162; G03F 7/0041; G03F 7/202

(57) ABSTRACT

A hardmask composition, a hardmask layer, and a method of forming patterns, the hardmask composition including a polymer including a structural unit represented by Chemical Formula 1; and a solvent,

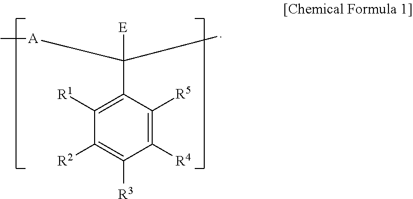

### CROSS-REFERENCE TO RELATED APPLICATION

Korean Patent Application No. 10-2019-0127125, filed on Oct. 14, 2019, in the Korean Intellectual Property Office, and entitled: “Hardmask Composition, Hardmask Layer and Method of Forming Patters,” is incorporated by reference herein in its entirety.

### BACKGROUND

### 1. Field

Embodiments relate to a hardmask composition, a hardmask layer including a cured product of the hardmask composition, and a method of forming patterns using the hardmask composition.

### 2. Description of the Related Art

Recently, the semiconductor industry has developed to an ultra-fine technique having a pattern of several to several tens of nanometer size. Such ultrafine techniques use effective lithographic techniques.

Some lithographic techniques may include providing a material layer on a semiconductor substrate; coating a photoresist layer thereon; exposing and developing the same to provide a photoresist pattern; and etching a material layer using the photoresist pattern as a mask.

### SUMMARY

The embodiments may be realized by providing a hardmask composition including a polymer including a structural unit represented by Chemical Formula 1; and a solvent,

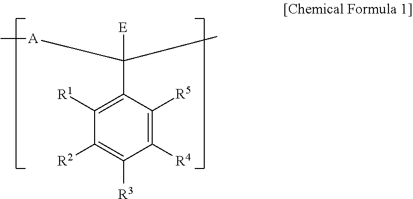

wherein, in Chemical Formula 1, A is a substituted or unsubstituted pyrenylene group, E is hydrogen, deuterium, a substituted or unsubstituted C1 to C30 alkyl group, a substituted or unsubstituted C6 to C30 aryl group, a halogen, a nitro group, an amino group, a hydroxy group, or a combination thereof, R¹ to R⁵ are independently hydrogen, deuterium, a hydroxy group, a substituted or unsubstituted C1 to C30 alkoxy group, a substituted or unsubstituted C1 to C30 alkyl group, a substituted or unsubstituted C2 to C30 alkenyl group, a substituted or unsubstituted C2 to C30 alkynyl group, a substituted or unsubstituted C1 to C30 heteroalkyl group, a substituted or unsubstituted C3 to C30 cycloalkyl group, a substituted or unsubstituted C6 to C30 aryl group, a substituted or unsubstituted C3 to C30 heterocyclic group, or a combination thereof, and at least two of R¹ to R⁵ are independently a hydroxy group, a substituted or unsubstituted C1 to C30 alkoxy group, or a combination thereof.

A may be an unsubstituted pyrenylene group or a pyrenylene group substituted with at least one substituent, and the at least one substituent may include deuterium, a hydroxy group, a substituted or unsubstituted C1 to C30 alkoxy group, a substituted or unsubstituted C1 to C30 alkyl group, a substituted or unsubstituted C2 to C30 alkenyl group, a substituted or unsubstituted C2 to C30 alkynyl group, a substituted or unsubstituted C1 to C30 heteroalkyl group, a substituted or unsubstituted C3 to C30 cycloalkyl group, a substituted or unsubstituted C6 to C30 aryl group, a substituted or unsubstituted C3 to C30 heterocyclic group, or a combination thereof.

A may be an unsubstituted pyrenylene group or a pyrenylene group substituted with at least one hydroxy group.

Two or three of R¹ to R⁵ may be independently a hydroxy group, a substituted or unsubstituted methoxy group, a substituted or unsubstituted ethoxy group, a substituted or unsubstituted propoxy group, a substituted or unsubstituted butoxy group, or a combination thereof.

R³ and R⁴ may be independently a hydroxy group, a substituted or unsubstituted methoxy group, a substituted or unsubstituted ethoxy group, a substituted or unsubstituted propoxy group, a substituted or unsubstituted butoxy group, or a combination thereof; R³ and R⁵ may be independently a hydroxy group, a substituted or unsubstituted methoxy group, a substituted or unsubstituted ethoxy group, a substituted or unsubstituted propoxy group, a substituted or unsubstituted butoxy group, or a combination thereof; or R¹, R³, and R⁵ may be independently a hydroxy group, a substituted or unsubstituted methoxy group, a substituted or unsubstituted ethoxy group, a substituted or unsubstituted propoxy group, a substituted or unsubstituted butoxy group, or a combination thereof.

The structural unit represented by Chemical Formula 1 may be represented by one of Chemical Formulae 2 to 4,

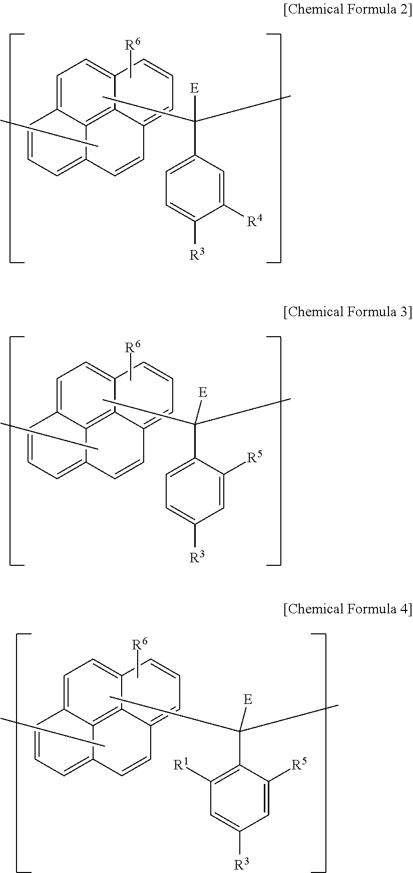

in Chemical Formulae 2 to 4, E may be hydrogen, deuterium, a substituted or unsubstituted C1 to C30 alkyl group, a substituted or unsubstituted C6 to C30 aryl group, a halogen, a nitro group, an amino group, a hydroxy group, or a combination thereof, R¹, R³, R⁴, and R⁵ may be independently a hydroxy group, a substituted or unsubstituted methoxy group, a substituted or unsubstituted ethoxy group, a substituted or unsubstituted propoxy group, a substituted or unsubstituted butoxy group, or a combination thereof, and R⁶ may be hydrogen, a hydroxy group, a substituted or unsubstituted methoxy group, a substituted or unsubstituted ethoxy group, a substituted or unsubstituted propoxy group, a substituted or unsubstituted butoxy group or a combination thereof.

The structural unit represented by Chemical Formula 1 may be formed from a reaction mixture including a substituted or unsubstituted pyrene, and benzaldehyde substituted with at least two substituents, and the substituents are each independently a hydroxy group, a substituted or unsubstituted C1 to C30 alkoxy group, or a combination thereof.

The substituted or unsubstituted pyrene may be unsubstituted pyrene or hydroxypyrene.

The benzaldehyde substituted with at least two substituents may be dihydroxybenzaldehyde, hydroxymethoxybenzaldehyde, hydroxyethoxybenzaldehyde, hydroxypropoxybenzaldehyde, hydroxybutoxybenzaldehyde, trihydroxybenzaldehyde, or a combination thereof.

The embodiments may be realized by providing a hardmask layer comprising a cured product of the hardmask composition according to an embodiment.

The embodiments may be realized by providing a method of forming patterns, the method including applying the hardmask composition according to an embodiment on a material layer and heat-treating the resultant to form a hardmask layer, forming a photoresist layer on the hardmask layer, exposing and developing the photoresist layer to form a photoresist pattern, selectively removing the hardmask layer using the photoresist pattern to expose a portion of the material layer, and etching an exposed portion of the material layer.

### DETAILED DESCRIPTION

Example embodiments will now be described more fully hereinafter; however, they may be embodied in different forms and should not be construed as limited to the embodiments set forth herein. Rather, these embodiments are provided so that this disclosure will be thorough and complete, and will fully convey exemplary implementations to those skilled in the art.

It will also be understood that when a layer or element is referred to as being “on” another layer or element, it can be directly on the other layer or element, or intervening layers may also be present. In addition, it will also be understood that when an element is referred to as being “between” two elements, it can be the only element between the two elements, or one or more intervening elements may also be present.

As used herein, when a definition is not otherwise provided, “substituted” refers to replacement of a hydrogen atom of a compound by a substituent selected from deuterium, a halogen atom (F, Br, Cl, or I), a hydroxy group, a nitro group, a cyano group, an amino group, an azido group, an amidino group, a hydrazino group, a hydrazono group, a carbonyl group, a carbamyl group, a thiol group, an ester group, a carboxyl group or a salt thereof, a sulfonic acid group or a salt thereof, a phosphoric acid group or a salt thereof, a C1 to C30 alkyl group, a C2 to C30 alkenyl group, a C2 to C30 alkynyl group, a C6 to C30 aryl group, a C7 to C30 arylalkyl group, a C1 to C30 alkoxy group, a C1 to C30 heteroalkyl group, a C3 to C30 heteroarylalkyl group, a C3 to C30 cycloalkyl group, a C3 to C15 cycloalkenyl group, a C6 to C15 cycloalkynyl group, a C2 to C30 heterocyclic group, and a combination thereof.

In addition, two adjacent substituents of the substituted halogen atom (F, Br, Cl, or I), a hydroxy group, a nitro group, a cyano group, an amino group, an azido group, an amidino group, a hydrazino group, a hydrazono group, a carbonyl group, a carbamyl group, a thiol group, an ester group, a carboxyl group or salt thereof, sulfonic acid group or salt thereof, phosphoric acid group or salt thereof, a C1 to C30 alkyl group, a C2 to C30 alkenyl group, a C2 to C30 alkynyl group, a C6 to C30 aryl group, a C7 to C30 arylalkyl group, a C1 to C30 alkoxy group, a C1 to C30 heteroalkyl group, a C3 to C30 heteroarylalkyl group, a C3 to C30 cycloalkyl group, a C3 to C15 cycloalkenyl group, a C6 to C15 cycloalkynyl group, and C2 to C30 heterocyclic group may be fused to form a ring. For example, the substituted C6 to C30 aryl group may be fused with another adjacent substituted C6 to C30 aryl group to form a substituted or unsubstituted fluorene ring.

As used herein, when a definition is not otherwise provided, “hetero” refers to one including 1 to 3 heteroatoms selected from N, O, S, Se, and P.

As used herein, “aryl group” refers to a group including at least one hydrocarbon aromatic moiety, and includes hydrocarbon aromatic moieties linked by a single bond and hydrocarbon aromatic moieties fused directly or indirectly to provide a non-aromatic fused ring. The aryl group may include a monocyclic, polycyclic, or fused polycyclic (i.e., rings sharing adjacent pairs of carbon atoms) functional group.

As used herein, “heterocyclic group” is a concept including a heteroaryl group, and may include at least one hetero atom selected from N, O, S, P, and Si instead of carbon (C) in a cyclic compound such as an aryl group, a cycloalkyl group, a fused ring thereof, or a combination thereof. When the heterocyclic group is a fused ring, the entire ring or each ring of the heterocyclic group may include one or more heteroatoms.

More specifically, the substituted or unsubstituted aryl group may be a substituted or unsubstituted phenyl group, a substituted or unsubstituted naphthyl group, a substituted or unsubstituted anthracenyl group, a substituted or unsubstituted phenanthryl group, a substituted or unsubstituted naphthacenyl group, a substituted or unsubstituted pyrenyl group, a substituted or unsubstituted biphenyl group, a substituted or unsubstituted terphenyl group, a substituted or unsubstituted quaterphenyl group, a substituted or unsubstituted chrysenyl group, a substituted or unsubstituted triphenylenyl group, a substituted or unsubstituted perylenyl group, a substituted or unsubstituted indenyl group, a substituted or unsubstituted fluorenyl group, a combination thereof, or a combined fused ring of the foregoing groups.

More specifically, the substituted or unsubstituted heterocyclic group may be a substituted or unsubstituted furanyl group, a substituted or unsubstituted thiophenyl group, a substituted or unsubstituted pyrrolyl group, a substituted or unsubstituted pyrazolyl group, a substituted or unsubstituted imidazolyl group, a substituted or unsubstituted triazolyl group, a substituted or unsubstituted oxazolyl group, a substituted or unsubstituted thiazolyl group, a substituted or unsubstituted oxadiazolyl group, a substituted or unsubstituted thiadiazolyl group, a substituted or unsubstituted pyridinyl group, a substituted or unsubstituted pyrimidinyl group, a substituted or unsubstituted pyrazinyl group, a substituted or unsubstituted triazinyl group, a substituted or unsubstituted benzofuranyl group, a substituted or unsubstituted benzothiophenyl group, a substituted or unsubstituted benzimidazolyl group, a substituted or unsubstituted indolyl group, a substituted or unsubstituted quinolinyl group, a substituted or unsubstituted isoquinolinyl group, a substituted or unsubstituted quinazolinyl group, a substituted or unsubstituted quinoxalinyl group, a substituted or unsubstituted naphthyridinyl group, a substituted or unsubstituted benzoxazinyl group, a substituted or unsubstituted benzthiazinyl group, a substituted or unsubstituted acridinyl group, a substituted or unsubstituted phenazinyl group, a substituted or unsubstituted phenothiazinyl group, a substituted or unsubstituted phenoxazinyl group, a substituted or unsubstituted dibenzofuranyl group, a substituted or unsubstituted dibenzothiphenyl group, a substituted or unsubstituted carbazolyl group, a substituted or unsubstituted pyridoindolyl group, a substituted or unsubstituted benzopyridooxazinyl group, a substituted or unsubstituted benzopyridothiazinyl group, a substituted or unsubstituted 9,9-dimethyl 9,10 dihydroacridinyl group, a combination thereof, or a combined fused ring of the foregoing groups. In one example of the present invention, the heterocyclic group or the heteroaryl group may be a pyrrole group, an indolyl group, or a carbazolyl group.

As used herein, the polymer is meant to include an oligomer and a polymer.

Hereinafter, a hardmask composition according to an embodiment is described.

The hardmask composition according to an embodiment may include a polymer and a solvent.

The polymer may include a main chain including an aromatic ring and a side chain including an aromatic ring bonded to the main chain and substituted with at least two substituents.

The main chain including the aromatic ring may include a condensed aromatic ring, and may include, e.g., substituted or unsubstituted pyrene. The side chain including the aromatic ring substituted with at least two substituents may include benzene (e.g., a phenyl group) substituted with at least two substituents. In an implementation, the substituent may be a hydrophilic functional group, e.g., a hydroxy group or a substituted or unsubstituted alkoxy group.

In an implementation, by including an aromatic ring having a high carbon content in the main chain, a hard film-like polymer layer may be formed, thereby improving etch resistance. In an implementation, by including an aromatic ring having a hydrophilic functional group in the side chain, solubility for a solvent may be improved.

In an implementation, the polymer may include a structural unit (e.g., repeating unit) represented by Chemical Formula 1.

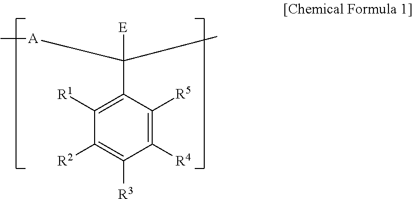

In Chemical Formula 1,

A may be or may include, e.g., a substituted or unsubstituted pyrenylene group,

E may be or may include, e.g., hydrogen, deuterium, a substituted or unsubstituted C1 to C30 alkyl group, a substituted or unsubstituted C6 to C30 aryl group, a halogen, a nitro group, an amino group, a hydroxy group, or a combination thereof, and

R¹ to R⁵ may each independently be or include, e.g., hydrogen, deuterium, a hydroxy group, a substituted or unsubstituted C1 to C30 alkoxy group, a substituted or unsubstituted C1 to C30 alkyl group, a substituted or unsubstituted C2 to C30 alkenyl group, a substituted or unsubstituted C2 to C30 alkynyl group, a substituted or unsubstituted C1 to C30 heteroalkyl group, a substituted or unsubstituted C3 to C30 cycloalkyl group, a substituted or unsubstituted C6 to C30 aryl group, a substituted or unsubstituted C3 to C30 heterocyclic group, or a combination thereof.

In an implementation, at least two of R¹ to R⁵ may each independently be or include, e.g., a hydroxy group, a substituted or unsubstituted C1 to C30 alkoxy group, or a combination thereof.

In an implementation, A may be, e.g., an unsubstituted pyrenylene group or a pyrenylene group independently substituted with at least one substituent. In an implementation, each substituent may independently be or include, e.g., deuterium, a hydroxy group, a substituted or unsubstituted C1 to C30 alkoxy group, a substituted or unsubstituted C1 to C30 alkyl group, a substituted or unsubstituted C2 to C30 alkenyl group, a substituted or unsubstituted C2 to C30 alkynyl group, a substituted or unsubstituted C1 to C30 heteroalkyl group, a substituted or unsubstituted C3 to C30 cycloalkyl group, a substituted or unsubstituted C6 to C30 aryl group, a substituted or unsubstituted C3 to C30 heterocyclic group, or a combination thereof.

In an implementation, in A, when a number of substituents is plural, all of the substituents may be substituted on the same ring among the rings in the pyrene, or may be substituted on different rings among the rings in the pyrene.

In an implementation, A may be an unsubstituted pyrenylene group, a pyrenylene group substituted with one substituent, or a pyrenylene group substituted with two substituents.

In an implementation, A may be an unsubstituted pyrenylene group, a pyrenylene group substituted with at least one hydroxy group, or a pyrenylene group substituted with at least one C1 to C30 alkoxy group. In an implementation, the C1 to C30 alkoxy group may be a substituted or unsubstituted methoxy group, a substituted or unsubstituted ethoxy group, a substituted or unsubstituted propoxy group, a substituted or unsubstituted butoxy group, or a combination thereof.

In an implementation, A may be an unsubstituted pyrenylene group or a pyrenylene group substituted with one or two hydroxy groups. In an implementation, A may be an unsubstituted pyrenylene group, a 1-hydroxypyrenylene group, or a 2-hydroxypyrenylene group.

As described above, the polymer may include a phenyl group substituted with at least two hydrophilic functional groups in the side chain. The phenyl group substituted with the at least two hydrophilic functional groups in the side chain and the substituted or unsubstituted pyrenylene group in the main chain may be bonded to a tertiary carbon or a quaternary carbon. In an implementation, the polymer may have increased solubility in a solvent and may effectively be applied to a solution process such as spin coating, and may have improved etch resistance to a N₂/O₂ mixed gas and provide a polymer layer having improved film density.

In an implementation, R¹ to R⁵ may each independently be, e.g., hydrogen, deuterium, a hydroxy group, a substituted or unsubstituted C1 to C30 alkoxy group, or combination thereof. In an implementation, R¹ to R⁵ may each independently be, e.g., hydrogen, deuterium, a hydroxy group, a substituted or unsubstituted methoxy group, a substituted or unsubstituted ethoxy group, a substituted or unsubstituted propoxy group, a substituted or unsubstituted butoxy group, or a combination thereof.

In an implementation, 2 to 5 of R¹ to R⁵ may independently be, e.g., a hydroxy group, a substituted or unsubstituted C1 to C30 alkoxy group, or a combination thereof. In an implementation, 2 or 3 of R¹ to R⁵ may independently be, e.g., a hydroxy group, a substituted or unsubstituted C1 to C30 alkoxy group, or a combination thereof.

In an implementation, R³ may be a hydroxy group, a substituted or unsubstituted C1 to C30 alkoxy group, or a combination thereof, e.g., a hydroxy group.

In an implementation, R³ and R⁴ may each independently be, e.g., a hydroxy group, a substituted or unsubstituted C1 to C30 alkoxy group, or a combination thereof.

In an implementation, R³ and R⁵ may each independently be, e.g., a hydroxy group, a substituted or unsubstituted C1 to C30 alkoxy group, or a combination thereof.

In an implementation, R¹, R³ and R⁵ may each independently be, e.g., a hydroxy group, a substituted or unsubstituted C1 to C30 alkoxy group, or a combination thereof.

In an implementation, R³ may be a hydroxy group, R⁴ may be a hydroxy group or a substituted or unsubstituted C1 to C30 alkoxy group; R³ and R⁵ may be a hydroxy group; or R¹, R³, and R⁵ may be a hydroxy group.

In an implementation, at least two of R¹ to R⁵ may independently be, e.g., a hydroxy group, a substituted or unsubstituted methoxy group, a substituted or unsubstituted ethoxy group, a substituted or unsubstituted propoxy group, a substituted or unsubstituted butoxy group, or a combination thereof.

In an implementation, two to five of R¹ to R⁵ may independently be, e.g., a hydroxy group, a substituted or unsubstituted methoxy group, a substituted or unsubstituted ethoxy group, a substituted or unsubstituted propoxy group, a substituted or unsubstituted butoxy group, or a combination thereof. In an implementation, 2 or 3 of R¹ to R⁵ may independently be, e.g., a hydroxy group, a substituted or unsubstituted methoxy group, a substituted or unsubstituted ethoxy group, a substituted or unsubstituted propoxy group, a substituted or unsubstituted butoxy group, or a combination thereof.

In an implementation, R³ may be a hydroxy group, a substituted or unsubstituted methoxy group, a substituted or unsubstituted ethoxy group, a substituted or unsubstituted propoxy group, a substituted or unsubstituted butoxy group, or a combination thereof, e.g., a hydroxy group.

In an implementation, R³ and R⁴ may each independently be, e.g., a hydroxy group, a substituted or unsubstituted methoxy group, a substituted or unsubstituted ethoxy group, a substituted or unsubstituted propoxy group, a substituted or unsubstituted butoxy group, or a combination thereof.

In an implementation, R³ and R⁵ may each independently be, e.g., a hydroxy group, a substituted or unsubstituted methoxy group, a substituted or unsubstituted ethoxy group, a substituted or unsubstituted propoxy group, a substituted or unsubstituted butoxy group, or a combination thereof.

In an implementation, R¹, R³, and R⁵ may each independently be, e.g., a hydroxy group, a substituted or unsubstituted methoxy group, a substituted or unsubstituted ethoxy group, a substituted or unsubstituted propoxy group, a substituted or unsubstituted butoxy group, or a combination thereof.

In an implementation, R³ may be a hydroxy group, R⁴ may be a hydroxy group, a substituted or unsubstituted methoxy group, a substituted or unsubstituted ethoxy group, a substituted or unsubstituted propoxy group or a substituted or unsubstituted butoxy group; R³ and R⁵ may be a hydroxy group; or R¹, R³, and R⁵ may be a hydroxy group.

In an implementation, R² may be hydrogen.

In an implementation, the structural unit represented by Chemical Formula 1 may be represented by one of Chemical Formulae 2 to 4.

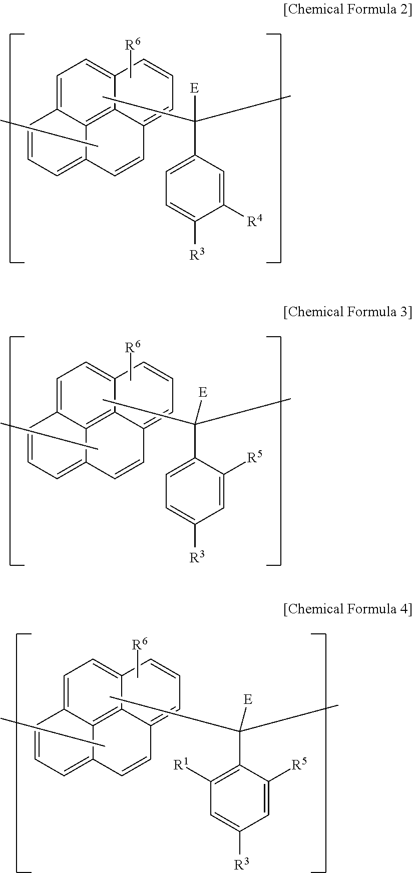

In Chemical Formulae 2 to 4,

E, R¹, R³, R⁴, and R⁵ may be defined the same as described above, and

R⁶ may be or may include, e.g., hydrogen, a hydroxy group, a substituted or unsubstituted C1 to C30 alkoxy group, or a combination thereof.

In an implementation, R⁶ may be, e.g., hydrogen, a hydroxy group, a substituted or unsubstituted methoxy group, a substituted or unsubstituted ethoxy group, a substituted or unsubstituted propoxy group, a substituted or unsubstituted butoxy group, or a combination thereof.

In an implementation, the structural unit represented by Chemical Formula 1 may be derived, formed, or prepared from a reaction mixture including a substituted or unsubstituted pyrene and benzaldehyde substituted with at least two substituents. In an implementation, each substituent may independently be, e.g., deuterium, a hydroxy group, a substituted or unsubstituted C1 to C30 alkoxy group, a substituted or unsubstituted C1 to C30 alkyl group, a substituted or unsubstituted C2 to C30 alkenyl group, a substituted or unsubstituted C2 to C30 alkynyl group, a substituted or unsubstituted C1 to C30 heteroalkyl group, a substituted or unsubstituted C3 to C30 cycloalkyl group, a substituted or unsubstituted C6 to C30 aryl group, a substituted or unsubstituted C3 to C30 heterocyclic group, or a combination thereof, and desirably independently a hydroxy group, a substituted or unsubstituted C1 to C30 alkoxy group, or a combination thereof.

In an implementation, the structural unit may be obtained through a condensation reaction of the reaction mixture.

In an implementation, the substituted or unsubstituted pyrene may be an unsubstituted pyrene or a pyrene substituted with at least one substituent (that is the same as or different from each other when two or more substituents are present). In an implementation, when the number of substituents is plural, all of the substituents may be substituted on the same ring among the rings in the pyrene, or may be substituted on different rings among the rings in the pyrene.

In an implementation, the substituted or unsubstituted pyrene may be an unsubstituted pyrene, a pyrene substituted with one substituent, or a pyrene substituted with two substituents.

In an implementation, the substituted or unsubstituted pyrene may be an unsubstituted pyrene, a pyrene substituted with at least one hydroxy group, a pyrene substituted with at least one substituted or unsubstituted C1 to C30 alkoxy group, or a combination thereof. In an implementation, the substituted or unsubstituted C1 to C30 alkoxy group may be a substituted or unsubstituted methoxy group, a substituted or unsubstituted ethoxy group, a substituted or unsubstituted propoxy group, a substituted or unsubstituted butoxy group, or a combination thereof.

In an implementation, the substituted or unsubstituted pyrene may be an unsubstituted pyrene or a pyrene substituted with one or two hydroxy groups, e.g., pyrene, 1-hydroxypyrene, or 2-hydroxypyrene.

In an implementation, the benzaldehyde substituted with at least two substituents may be benzaldehyde substituted with 2 to 5 substituents that are the same or different from each other, e.g., benzaldehyde substituted with 2 or 3 substituents.

In an implementation, the benzaldehyde substituted with at least two substituents may be a benzaldehyde substituted with at least two hydroxy groups, a benzaldehyde substituted with at least two substituted or unsubstituted C1 to C30 alkoxy groups, a benzaldehyde substituted with at least one hydroxy group and at least one substituted or unsubstituted C1 to C30 alkoxy group, or a combination thereof. In an implementation, the benzaldehyde substituted with at least two substituents may be a benzaldehyde substituted with two hydroxy groups, a benzaldehyde substituted with three hydroxy groups, a benzaldehyde substituted with two substituted or unsubstituted C1 to C30 alkoxy groups, a benzaldehyde substituted with three substituted or unsubstituted C1 to C30 alkoxy groups, a benzaldehyde substituted with one hydroxy group and one substituted or unsubstituted C1 to C30 alkoxy group, or a combination thereof. In an implementation, the substituted or unsubstituted C1 to C30 alkoxy group may be a substituted or unsubstituted methoxy group, a substituted or unsubstituted ethoxy group, a substituted or unsubstituted propoxy group, a substituted or unsubstituted butoxy group, or a combination thereof.

In an implementation, the benzaldehyde substituted with at least two substituents may be, e.g., dihydroxybenzaldehyde, hydroxymethoxybenzaldehyde, hydroxyethoxybenzaldehyde, hydroxypropoxybenzaldehyde, hydroxybutoxybenzaldehyde, trihydroxybenzaldehyde, or a combination thereof.

In an implementation, the benzaldehyde substituted with at least two substituents may be, e.g., 3,4-dihydroxybenzaldehyde, 2,4-dihydroxybenzaldehyde, 4-hydroxy-3-methoxybenzaldehyde or 2,4,6-trihydroxybenzaldehyde.

The polymer may include one or more structural units represented by Chemical Formula 1. In an implementation, each structural unit represented by Chemical Formula 1 (of a plurality of the structural units) may be the same or different from each other.

The polymer may include the structural unit represented by Chemical Formula 1 as a plurality of repeating units, and the number and arrangement of the repeating units may be a suitable number and arrangement.

The polymer may further include one or more other structural units, other than the structural units described above, and the number and arrangement of the structural units may be a suitable number and arrangement.

The polymer may have a weight average molecular weight of, e.g., about 500 to about 200,000. In an implementation, the polymer may have a weight average molecular weight of, e.g., about 1,000 to about 100,000, about 1,200 to about 50,000, or about 1,500 to about 10,000. When the polymer has a weight average molecular weight within the ranges, the polymer may be optimized by adjusting the amount of carbon and solubility in a solvent.

The solvent included in the hardmask composition may be a suitable solvent having sufficient solubility or dispersibility with respect to the polymer. In an implementation, the solvent may include, e.g., propylene glycol, propylene glycol diacetate, methoxy propanediol, diethylene glycol, diethylene glycol butylether, tri(ethylene glycol)monomethylether, propylene glycol monomethylether, propylene glycol monomethylether acetate, cyclohexanone, ethyllactate, gamma-butyrolactone, N,N-dimethyl formamide, N,N-dimethyl acetamide, methylpyrrolidone, methylpyrrolidinone, acetylacetone, or ethyl 3-ethoxypropionate.

The polymer may be included in an amount of, e.g., about 0.1 wt % to about 50 wt %, about 0.5 wt % to about 40 wt %, about 1 wt % to about 30 wt %, or about 3 wt % to 20 wt %, based on a total weight of the total amount of the hardmask composition. When the polymer is included within the ranges, a thickness, surface roughness and planarization of the hardmask may be controlled.

The hardmask composition may further include an additive, e.g., a surfactant, a cross-linking agent, a thermal acid generator, or a plasticizer.

The surfactant may include, e.g., a fluoroalkyl compound, an alkylbenzene sulfonate salt, an alkyl pyridinium salt, polyethylene glycol, or a quaternary ammonium salt.

The cross-linking agent may include, e.g., a melamine cross-linking agent, substituted urea cross-linking agent, or a polymer cross-linking agent. In an implementation, it may be a cross-linking agent having at least two cross-linking forming substituents, e.g., methoxymethylated glycoluril, butoxymethylated glycoluril, methoxymethylated melamine, butoxymethylated melamine, methoxymethylated benzoguanamine, butoxymethylated benzoguanamine, methoxymethylatedurea, butoxymethylatedurea, methoxymethylated thiourea, butoxymethylated thiourea, or the like.

The cross-linking agent may be a cross-linking agent having high heat resistance. The cross-linking agent having high heat resistance may be a compound including a cross-linking substituent including an aromatic ring (e.g., a benzene ring or a naphthalene ring) in the molecule.

The thermal acid generator include, e.g., an acidic compound such as p-toluene sulfonic acid, trifluoromethane sulfonic acid, pyridiniump-toluenesulfonic acid, salicylic acid, sulfosalicylic acid, citric acid, benzoic acid, hydroxybenzoic acid, naphthalenecarbonic acid, or the like, or 2,4,4,6-tetrabromocyclohexadienone, benzointosylate, 2-nitrobenzyltosylate, other organosulfonic acid alkylester, or the like.

The additive may be included in an amount of, e.g., about 0.001 to 40 parts by weight, about 0.01 to 30 parts by weight, or about 0.1 to 20 parts by weight, based on 100 parts by weight of the hardmask composition. Within these ranges, solubility may be improved while optical properties of the hardmask composition are not changed.

According to another embodiment, an organic layer produced using the hardmask composition is provided. The organic layer may be, e.g., formed by coating the hardmask composition on a substrate and heat-treating it for curing and may include, e.g., a hardmask layer, a planarization layer, a sacrificial layer, a filler, or the like for an electronic device.

According to another embodiment, a hardmask layer including a cured product of the aforementioned hardmask composition is provided.

In an implementation, the cured product may include condensed polycyclic aromatic hydrocarbons.

In an implementation, the cured product may include condensed polycyclic aromatic hydrocarbons, and it may exhibit high etch resistance that may withstand etching gases and chemical liquids exposed in subsequent processes including etching processes.

Hereinafter, a method of forming patterns using the aforementioned hardmask composition is described.

A method of forming patterns according to an embodiment may include forming a material layer on a substrate, applying a hardmask composition including the aforementioned polymer and solvent on the material layer, heat-treating the hardmask composition to form a hardmask layer, forming a photoresist layer on the hardmask layer, exposing and developing the photoresist layer to form a photoresist pattern, selectively removing the hardmask layer using the photoresist pattern to expose a part of the material layer, and etching the exposed part of the material layer.

The substrate may include, e.g., a silicon wafer, a glass substrate, or a polymer substrate.

The material layer may be a material to be finally patterned, e.g., a metal layer such as an aluminum layer and a copper layer, a semiconductor layer such as a silicon layer, or an insulation layer such as a silicon oxide layer and a silicon nitride layer. The material layer may be formed through a method such as a chemical vapor deposition (CVD) process.

The hardmask composition is the same as described above, and may be applied by spin-on coating in a form of a solution. In an implementation, an applied thickness of the hardmask composition may be, e.g., about 50 Å to about 200,000 Å.

The heat-treating of the hardmask composition may be performed, e.g., at about 100° C. to about 700° C. for about 10 seconds to about 1 hour.

In an implementation, the method may further include forming a silicon-containing thin layer on the hardmask layer. The silicon-containing thin layer may be formed of a material, e.g. SiCN, SiOC, SiON, SiOCN, SiC, SiO, SiN, or the like.

In an implementation, the method may further include forming a bottom antireflective coating (BARC) on the upper surface of the silicon-containing thin layer or on the upper surface hardmask layer before forming the photoresist layer.

Exposure of the photoresist layer may be performed using, e.g., ArF, KrF, or EUV. After exposure, heat-treating may be performed at, e.g., about 100° C. to about 700° C.

The etching process of the exposed portion of the material layer may be performed through a dry etching process using an etching gas and the etching gas may include, e.g., N₂/O₂, CHF₃, CF₄, Cl₂, BCl₃, or a mixed gas thereof.

The etched material layer may be formed in a plurality of patterns, and the plurality of patterns may be a metal pattern, a semiconductor pattern, an insulation pattern, and the like, for example diverse patterns of a semiconductor integrated circuit device.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### Synthesis of Polymers

### Synthesis Example 1

1-hydroxypyrene (21.8 g, 0.1 mol) and 3,4-dihydroxybenzaldehyde (13.8 g, 0.1 mol) were added to a 250 ml flask, and then, a solution prepared by dissolving p-toluene sulfonic acid monohydrate (0.57 g, 0.03 mmol) in 100 g of propylene glycol monomethyl ether acetate (PGMEA) was added thereto. The obtained mixture was stirred at 90° C. to perform a polymerization reaction, and when a weight average molecular weight reached 2,000 to 2,500, the reaction was completed. When the polymerization reaction was complete, the reactant was cooled down to ambient temperature, and then, 300 g of distilled water and 300 g of methanol were added thereto and then, vigorously stirred and allowed to stand. After removing a supernatant therefrom, precipitates therein were dissolved in 100 g of PGMEA, 300 g of methanol and 300 g of distilled water were added thereto and then, vigorously stirred and allowed to stand (a primary process). After removing the supernatant again, the precipitates therein were dissolved in 80 g of PGMEA (a secondary process). One primary process and one secondary process were regarded as one purification process, which was performed three times in total. After performing three purification processes, a polymer obtained therefrom was dissolved in 80 g of PGMEA, concentrated under a reduced pressure to remove residual methanol and distilled water to obtain a polymer including a structural unit (a repeating unit) represented by Chemical Formula 1a. (Mw: 2,455)

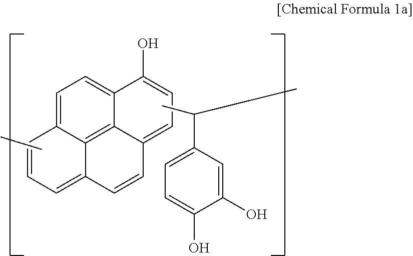

### Synthesis Example 2

A polymer including a structural unit (a repeating unit) represented by Chemical Formula 1b was synthesized according to the same method as Synthesis Example 1 except that 4-hydroxy-3-methoxybenzaldehyde (15.2 g, 0.1 mol) was used instead of the 3,4-dihydroxybenzaldehyde (13.8 g, 0.1 mol). (Mw: 2,785)

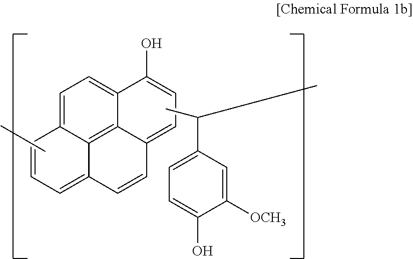

### Synthesis Example 3

A polymer including a structural unit (a repeating unit) represented by Chemical Formula 1c was synthesized according to the same method as Synthesis Example 1 except that 2,4,6-trihydroxybenzaldehyde (15.4 g, 0.1 mol) was used instead of the 3,4-dihydroxybenzaldehyde (13.8 g, 0.1 mol). (Mw: 2,127)

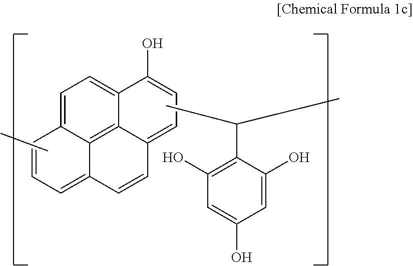

### Synthesis Example 4

A polymer including a structural unit (a repeating unit) represented by Chemical Formula 1d was synthesized according to the same method as Synthesis Example 1 except that pyrene (20.2 g, 0.1 mol) was used instead of the 1-hydroxypyrene (21.8 g, 0.1 mol), and 2,4-dihydroxybenzaldehyde (13.8 g, 0.1 mol) was used instead of the 3,4-dihydroxybenzaldehyde (13.8 g, 0.1 mol). (Mw: 2,086)

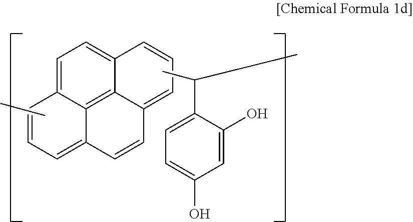

### Comparative Synthesis Example 1

A polymer including a structural unit (a repeating unit) represented by Chemical Formula A was synthesized according to the same method as Synthesis Example 1 except that 4-hydroxybenzaldehyde (12.2 g, 0.1 mol) was used instead of the 3,4-dihydroxybenzaldehyde (13.8 g, 0.1 mol). (Mw: 2,120)

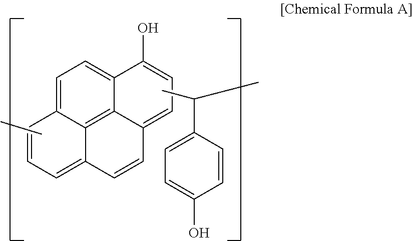

### Comparative Synthesis Example 2

A polymer including a structural unit (a repeating unit) represented by Chemical Formula B was synthesized according to the same method as Synthesis Example 1 except that pyrene (20.2 g, 0.1 mol) was used instead of the 1-hydroxypyrene (21.8 g, 0.1 mol), and 4-hydroxybenzaldehyde (12.2 g, 0.1 mol) was used instead of the 3,4-dihydroxybenzaldehyde (13.8 g, 0.1 mol). (Mw: 2,490)

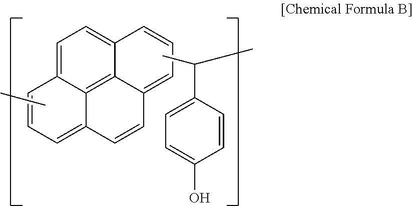

### Comparative Synthesis Example 3

A polymer including a structural unit (a repeating unit) represented by Chemical Formula C was synthesized according to the same method as Synthesis Example 1 except that pyrene (20.2 g, 0.1 mol) was used instead of the 1-hydroxypyrene (21.8 g, 0.1 mol), and benzaldehyde (10.6 g, 0.1 mol) was used instead of the 3,4-dihydroxybenzaldehyde (13.8 g, 0.1 mol). (Mw: 2,008)

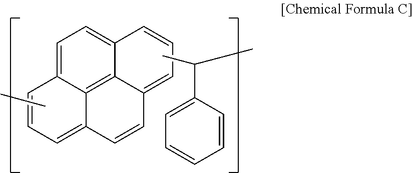

### Comparative Synthesis Example 4

A polymer including a structural unit (a repeating unit) represented by Chemical Formula D was synthesized according to the same method as Synthesis Example 1 except that 1-naphthol (14.4 g, 0.1 mol) was used instead of the 1-hydroxypyrene (21.8 g, 0.1 mol), and benzaldehyde (10.6 g, 0.1 mol) was used instead of the 3,4-dihydroxybenzaldehyde (13.8 g, 0.1 mol). (Mw: 2,011)

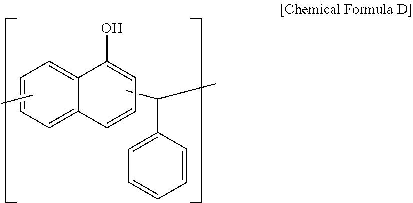

### Comparative Synthesis Example 5

A polymer including a structural unit (a repeating unit) represented by Chemical Formula E was synthesized according to the same method as Synthesis Example 1 except that 4,4′-(9H-fluorene-9,9-diyl)diphenol (35.0 g, 0.1 mol) was used instead of the 1-hydroxypyrene (21.8 g, 0.1 mol). (Mw: 2,472)

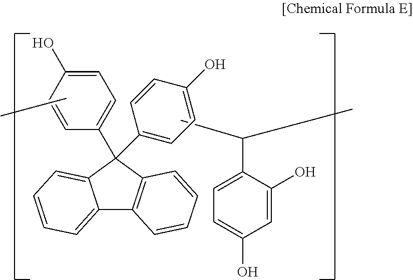

Evaluation 1. Solubility Evaluation

5.0 g of each of the polymers according to Synthesis Examples 1 to 4 and Comparative Synthesis Examples 1 to 5 were respectively uniformly dissolved in 45 g of PGMEA to prepare a 10 wt % solution, and then, filtered with a 0.1 μm TEFLON (tetrafluoroethylene) filter. The filtered samples were respectively subdivided and weighed by using an Al dish whose mass was known to measure initial mass of the solutions. Subsequently, the solvents were respectively dried therefrom in a 160° C. oven for 20 minutes, and the mass was measured again.

From a mass difference before and after the drying, each solid content of the solutions was calculated according to Calculation Equation 1.

Solid content (%)=(mass after drying at 160° C. for 20 minutes/initial mass of solution)×100 [Calculation Equation 1]

TABLE 1

| | Solubility |
|---|---|
| | in |
| | PGMEA |
| Synthesis Example 1 | O |
| Synthesis Example 2 | O |
| Synthesis Example 3 | O |
| Synthesis Example 4 | O |
| Comparative Synthesis Example 1 | Δ |
| Comparative Synthesis Example 2 | X |
| Comparative Synthesis Example 3 | X |
| Comparative Synthesis Example 4 | O |
| Comparative Synthesis Example 5 | O |

O : solid content of greater than or equal to 9%
Δ : solid content of greater than or equal to 8% and less than 9%
X : solid content of less than 8%

Referring to Table 1, the polymers according to Synthesis Examples 1 to 4 exhibited improved or equal solubility, compared with the polymers according to Comparative Synthesis Examples 1 to 5.

Formation of Hardmask Compositions

1.2 g of each of the polymers according to Synthesis Examples 1 to 4 and Comparative Synthesis Examples 1 to 5 were respectively uniformly dissolved in 18 g of PGMEA and filtered with a 0.1 μm TEFLON (tetrafluoroethylene) to prepare hardmask compositions according to Examples 1 to 4 and Comparative Examples 1 to 5.

Evaluation 2. Evaluation of Etch Resistance

The hardmask compositions according to Examples 1 to 4 and Comparative Examples 1 to 5 were respectively coated on a silicon wafer, and heat-treated on a hot plate at about 400° C. for 2 minutes to form organic films.

Thicknesses of the organic films were measured by using a ST5000 thin film thickness meter made by K-MAC, and subsequently, after dry-etched by using N₂/O₂ mixed gas (50 mT/300 W/10O₂/50N₂) for one minute, the thicknesses of the organic films were measured again.

Thickness differences of the organic films before and after the dry etching and etch time were used to calculate bulk etch rates (BER) according to Calculation Equation 2.

Etch rate (Å/s)=(thickness of initial organic film−thickness of organic film after etching)/etch time [Calculation Equation 2]

The results are shown in Table 2.

TABLE 2

| | Bulk |
|---|---|
| | etch |
| | rate |
| | (Å/s) |
| Example 1 | 22.21 |
| Example 2 | 22.35 |
| Example 3 | 21.67 |
| Example 4 | 22.72 |
| Comparative Example 1 | 23.05 |
| Comparative Example 2 | 24.25 |
| Comparative Example 3 | 27.60 |
| Comparative Example 4 | 28.53 |
| Comparative Example 5 | 27.21 |

Referring to Table 2, the organic films formed of the hardmask compositions according to Examples 1 to 4 exhibited sufficient etch resistance against etching gas and thus improved etch resistance, compared with the organic films formed of the hardmask compositions according to Comparative Examples 1 to 5.

Evaluation 3. Film Density

The hardmask compositions according to Examples 1 to 4 Comparative Examples 1 to 5 were respectively spin-coated on a silicon wafer and then heat-treated on a hot plate at about 400° C. for about 2 minutes to form about 1,000 Å-thick organic films.

Film density of the organic films was measured through an X-ray diffraction equipment (Malvern PaNalytical Ltd.).

The results are shown in Table 3.

TABLE 3

| | Film |
|---|---|
| | density |
| | (g/cm³) |
| Example 1 | 1.44 |
| Example 2 | 1.43 |
| Example 3 | 1.45 |
| Example 4 | 1.42 |
| Comparative Example 1 | 1.38 |
| Comparative Example 2 | 1.36 |
| Comparative Example 3 | 1.33 |
| Comparative Example 4 | 1.32 |
| Comparative Example 5 | 1.28 |

Referring to Table 3, the organic films formed of the hardmask compositions according to Examples 1 to 4 exhibited improved film density compared with the organic films formed of the hardmask compositions according to Comparative Examples 1 to 5.

By way of summation and review, according to small-sizing the pattern to be formed, it may be difficult to provide a fine pattern having an excellent profile using some lithographic techniques. Accordingly, an auxiliary layer, called a hardmask layer, may be formed between the material layer and the photoresist layer to provide a fine pattern.

One or more embodiments may provide a hardmask composition capable of improving etch resistance.

A solubility of the polymer and an etch resistance and a film density of the hardmask layer may be simultaneously secured.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A hardmask composition, comprising:
a polymer including a structural unit represented by Chemical Formula 1; and
a solvent, 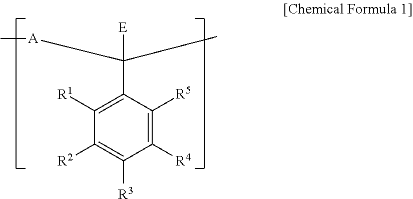
wherein, in Chemical Formula 1,
A is a substituted or unsubstituted pyrenylene group,
E is hydrogen, deuterium, a substituted or unsubstituted C1 to C30 alkyl group, a substituted or unsubstituted C6 to C30 aryl group, a halogen, a nitro group, an amino group, a hydroxy group, or a combination thereof,
R¹ to R⁵ are independently hydrogen, deuterium, a hydroxy group, a substituted or unsubstituted C1 to C30 alkoxy group, a substituted or unsubstituted C1 to C30 alkyl group, a substituted or unsubstituted C2 to C30 alkenyl group, a substituted or unsubstituted C2 to C30 alkynyl group, a substituted or unsubstituted C1 to C30 heteroalkyl group, a substituted or unsubstituted C3 to C30 cycloalkyl group, a substituted or unsubstituted C6 to C30 aryl group, a substituted or unsubstituted C3 to C30 heterocyclic group, or a combination thereof, and
at least two of R¹ to R⁵ are independently a hydroxy group, a substituted or unsubstituted C1 to C30 alkoxy group, or a combination thereof.

2. The hardmask composition as claimed in claim 1, wherein:
A is an unsubstituted pyrenylene group or a pyrenylene group substituted with at least one substituent, and
the at least one substituent includes deuterium, a hydroxy group, a substituted or unsubstituted C1 to C30 alkoxy group, a substituted or unsubstituted C1 to C30 alkyl group, a substituted or unsubstituted C2 to C30 alkenyl group, a substituted or unsubstituted C2 to C30 alkynyl group, a substituted or unsubstituted C1 to C30 heteroalkyl group, a substituted or unsubstituted C3 to C30 cycloalkyl group, a substituted or unsubstituted C6 to C30 aryl group, a substituted or unsubstituted C3 to C30 heterocyclic group, or a combination thereof.

3. The hardmask composition as claimed in claim 1, wherein A is an unsubstituted pyrenylene group or a pyrenylene group substituted with at least one hydroxy group.

4. The hardmask composition as claimed in claim 1, wherein two or three of R¹ to R⁵ are independently a hydroxy group, a substituted or unsubstituted methoxy group, a substituted or unsubstituted ethoxy group, a substituted or unsubstituted propoxy group, a substituted or unsubstituted butoxy group, or a combination thereof.

5. The hardmask composition as claimed in claim 1, wherein:
R³ and R⁴ are independently a hydroxy group, a substituted or unsubstituted methoxy group, a substituted or unsubstituted ethoxy group, a substituted or unsubstituted propoxy group, a substituted or unsubstituted butoxy group, or a combination thereof;
R³ and R⁵ are independently a hydroxy group, a substituted or unsubstituted methoxy group, a substituted or unsubstituted ethoxy group, a substituted or unsubstituted propoxy group, a substituted or unsubstituted butoxy group, or a combination thereof; or
R¹, R³, and R⁵ are independently a hydroxy group, a substituted or unsubstituted methoxy group, a substituted or unsubstituted ethoxy group, a substituted or unsubstituted propoxy group, a substituted or unsubstituted butoxy group, or a combination thereof.

6. The hardmask composition as claimed in claim 1, wherein:
the structural unit represented by Chemical Formula 1 is represented by one of Chemical Formulae 2 to 4, 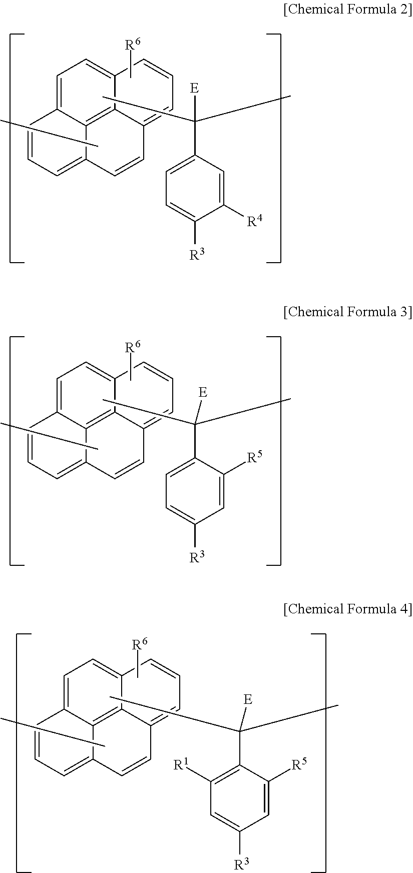
in Chemical Formulae 2 to 4,
E is hydrogen, deuterium, a substituted or unsubstituted C1 to C30 alkyl group, a substituted or unsubstituted C6 to C30 aryl group, a halogen, a nitro group, an amino group, a hydroxy group, or a combination thereof,
R¹, R³, R⁴, and R⁵ are independently a hydroxy group, a substituted or unsubstituted methoxy group, a substituted or unsubstituted ethoxy group, a substituted or unsubstituted propoxy group, a substituted or unsubstituted butoxy group, or a combination thereof, and
R⁶ is hydrogen, a hydroxy group, a substituted or unsubstituted methoxy group, a substituted or unsubstituted ethoxy group, a substituted or unsubstituted propoxy group, a substituted or unsubstituted butoxy group or a combination thereof.

7. The hardmask composition as claimed in claim 1, wherein:
the structural unit represented by Chemical Formula 1 is formed from a reaction mixture including:
a substituted or unsubstituted pyrene, and
benzaldehyde substituted with at least two substituents, and
the substituents are each independently a hydroxy group, a substituted or unsubstituted C1 to C30 alkoxy group, or a combination thereof.

8. The hardmask composition as claimed in claim 7, wherein the substituted or unsubstituted pyrene is unsubstituted pyrene or hydroxypyrene.

9. The hardmask composition as claimed in claim 7, wherein the benzaldehyde substituted with at least two substituents is dihydroxybenzaldehyde, hydroxymethoxybenzaldehyde, hydroxyethoxybenzaldehyde, hydroxypropoxybenzaldehyde, hydroxybutoxybenzaldehyde, trihydroxybenzaldehyde, or a combination thereof.

10. A hardmask layer comprising a cured product of the hardmask composition as claimed in claim 1.

11. A method of forming patterns, the method comprising:
applying the hardmask composition as claimed in claim 1 on a material layer and heat-treating the resultant to form a hardmask layer,
forming a photoresist layer on the hardmask layer,
exposing and developing the photoresist layer to form a photoresist pattern,
selectively removing the hardmask layer using the photoresist pattern to expose a portion of the material layer, and
etching an exposed portion of the material layer.
